(19) United States
(12) Patent Application Publication
(10) Pub. No.: US 2017/0164516 A1
(43) Pub. Date: Jun. 8, 2017

(54) Integrated Fluid Turbulator and Sealing System for Improved Thermal Management

(71) Applicant: Caterpillar Inc., Peoria, IL (US)

(72) Inventors: Chris J. Scolton, Edelstein, IL (US); Edward Choi, Edwards, IL (US); Jacob C. Wyss, Eureka, IL (US)

(73) Assignee: Caterpillar Inc., Peoria, IL (US)

(21) Appl. No.: 14/957,198

(22) Filed: Dec. 2, 2015

(51) Int. Cl. H05K 7/20; F28F 13/12; F28F 11/00

(52) U.S. Cl. CPC H05K 7/20281; F28F 11/00; F28F 13/12

(57) ABSTRACT

A cooling device for an electric component may include a manifold with a coolant section having a coolant inlet trough and a coolant outlet trough. The device may further include a fluid turbulator having a turbulator plate with turbulator fins extending upwardly therefrom, and turbulator inlet openings and outlet openings through the turbulator plate, and a turbulator carrier surrounding the turbulator plate. The fluid turbulator may be installed between the coolant section and the electric component so that a heat exchange reservoir is defined by bottom surface of the electric component, the turbulator plate top surface and the turbulator carrier. Coolant from a coolant source may flow into the coolant inlet trough, through the turbulator inlet opening into the heat exchange reservoir, and out of the heat exchange reservoir through the turbulator outlet opening into the coolant outlet trough to remove heat from the electric component.

### TECHNICAL FIELD

The present disclosure relates generally to a cooling device removing heat from electric components and, more particularly, to a cooling device having an integrated fluid turbulator and fluid sealing system.

### BACKGROUND

A wide array of applications are known for power electronic devices, such as power switches, transistors, and the like, in earthmoving and construction equipment and vehicles. For example, in industrial applications, insulated gate bipolar transistor (IGBT) modules, silicon controlled rectifiers (SCRs), field effect transistors (FETs), or other electric components are used to provide power to loads. In certain applications, for example, arrays of IGBT modules are employed to convert direct current power to alternating current waveforms and vice versa for application to loads. Such applications include motor drives in work machines. In work machines, a source of direct current is typically available from a battery or power supply system incorporating a battery or other direct or rotating energy converter. Power electronic devices are employed to convert this power to alternating current waveforms for driving one or more electric motors. The motors may serve to drive power transmission elements to propel the work machine.

During operation, the IGBT modules generate heat due to the flow of electricity through the electric components. As such, at least some known IGBT modules are coupled to a heat sink or other type of cooling device to dissipate heat generated by the IGBT module. Such cooling devices may incorporate a combination of fins removing heat from the IGBT, and a fluid (liquid or gas) flow for removing heat from the fins. One example of a cooling device is provided in U.S. Pat. No. 8,897,010, issued to Shepard on Nov. 25, 2014, entitled “High Performance Liquid Cooled Heat Sink for IGBT Modules.” The Shepard patent discloses methods and systems related to cooling an object. A heat sink assembly includes a base plate coupled to a first side of the object, a plurality of fins extending from the base plate, and a housing comprising a first manifold defining a plurality of first passages and a second manifold defining a plurality of second passages in fluid communication with the plurality of first passages. During operation, heat is transferred from the object through the base plate, and to the fins. To cool the fins, fluid is channeled through at least one of the first passages, toward at least one of the fins, and through at least one of the second passages.

### SUMMARY OF THE DISCLOSURE

In an aspect of the present disclosure, a cooling device for an electric component is disclosed. The electric component may have a base plate with a base plate top surface and a base plate bottom surface, and a heat generating component disposed on the base plate top surface. The cooling device may include a manifold having a manifold top surface defining a coolant section having a coolant inlet trough with a coolant inlet opening fluidly connecting the coolant inlet trough with a coolant source, and a coolant outlet trough with a coolant outlet opening fluidly connecting the coolant outlet trough with a coolant reservoir. The cooling device may further include a fluid turbulator having a turbulator plate having a turbulator plate top surface with at least one turbulator fin extending upwardly therefrom, a turbulator plate bottom surface, and a turbulator inlet opening and a turbulator outlet opening through the turbulator plate, and a turbulator carrier surrounding the turbulator plate and having a carrier top surface and a carrier bottom surface. The fluid turbulator may be installed at the coolant section with the carrier bottom surface facing and engaging the manifold top surface and surrounding the coolant inlet trough and the coolant outlet trough, and the base plate bottom surface facing and engaging the carrier top surface and surrounding the turbulator plate so that a heat exchange reservoir is defined by the base plate bottom surface, the turbulator plate top surface and the turbulator carrier. The turbulator inlet opening and the turbulator outlet opening may fluidly connect the coolant inlet trough and the coolant outlet trough, respectively, with the heat exchange reservoir so that coolant from the coolant source flows into the coolant inlet trough, through the turbulator inlet opening into the heat exchange reservoir, and out of the heat exchange reservoir through the turbulator outlet opening into the coolant outlet trough and to the coolant reservoir.

In another aspect of the present disclosure, a fluid turbulator for a cooling device for an electric component is disclosed. The fluid turbulator may include a turbulator plate having a turbulator plate top surface, a turbulator plate bottom surface, a turbulator plate outer edge, a plurality of turbulator fins extending upwardly from the turbulator plate top surface, a turbulator inlet opening through the turbulator plate and a turbulator outlet opening through the turbulator plate, with the turbulator plate having a turbulator plate thickness. The fluid turbulator may further include a turbulator carrier having a carrier top surface, a carrier bottom surface and a carrier thickness, and the turbulator carrier may surround the turbulator plate at the turbulator plate outer edge. The carrier thickness may be greater than the turbulator plate thickness, with the turbulator plate top surface being below the carrier top surface and the turbulator plate bottom surface being above the carrier bottom surface.

In a further aspect of the present disclosure, a cooling device for an electric component is disclosed. The electric component may have a base plate with a base plate top surface having a heat generating component disposed thereon and a base plate bottom surface. The cooling device may include a manifold having a manifold top surface defining a coolant section having coolant section cartridge recess, and coolant section inlet opening for placing the coolant section cartridge recess in fluid communication with a coolant source, and a coolant section outlet opening for placing the coolant section cartridge recess in fluid communication with a coolant reservoir. The cooling device may also include a coolant section cartridge having a coolant inlet trough with a coolant inlet opening, a coolant outlet trough with a coolant outlet opening, and a cartridge top surface. The coolant inlet opening and the coolant outlet opening may be positioned to align with the coolant section inlet opening and the coolant section outlet opening, respectively, when the coolant section cartridge is disposed within the coolant section cartridge recess. The cooling device may further include a fluid turbulator having a turbulator plate having a turbulator plate top surface with at least one turbulator fin extending upwardly therefrom, a turbulator plate bottom surface, and a turbulator inlet opening and a turbulator outlet opening through the turbulator plate, and a turbulator carrier surrounding the turbulator plate and having a carrier top surface and a carrier bottom surface. The coolant section cartridge may be installed at the coolant section with the coolant section cartridge disposed within the coolant section cartridge recess with the coolant inlet opening and the coolant outlet opening aligned with the coolant section inlet opening and the coolant section outlet opening, respectively. The fluid turbulator may be installed at the coolant section with the carrier bottom surface facing and engaging the manifold top surface and the cartridge top surface, and the base plate bottom surface facing and engaging the carrier top surface and surrounding the turbulator plate so that a heat exchange reservoir is defined by the base plate bottom surface, the turbulator plate top surface and the turbulator carrier. The turbulator inlet opening and the turbulator outlet opening may fluidly connect the coolant inlet trough and the coolant outlet trough, respectively, with the heat exchange reservoir so that coolant from the coolant source flows into the coolant inlet trough, through the turbulator inlet opening into the heat exchange reservoir, and out of the heat exchange reservoir through the turbulator outlet opening into the coolant outlet trough and to the coolant reservoir.

Additional aspects are defined by the claims of this patent.

### BRIEF DESCRIPTION OF THE DRAWINGS

FIG. 1 is a top isometric view of an embodiment of cooling device in accordance with the present disclosure having a plurality of IGBT cooling sections and corresponding IGBTs;

FIG. 2 is a top view of a manifold of the cooling device of FIG. 1;

FIG. 3 is a top isometric view of an embodiment of a fluid turbulator in accordance with the present disclosure of the cooling device of FIG. 1;

FIG. 4 is a top view of the fluid turbulator of FIG. 3;

FIG. 5 is a bottom isometric view of the turbulator of FIG. 3;

FIG. 6 is a cross-sectional view taken through line 6-6 in FIG. 1 of one coolant section of the cooling device of FIG. 1;

FIG. 7 is a top isometric view of an alternative embodiment of a cooling device in accordance with the present disclosure having a plurality of IGBT cooling sections and corresponding IGBTs;

FIG. 8 is a top isometric view of an embodiment of a coolant section cartridge in accordance with the present disclosure of the cooling device of FIG. 7;

FIG. 9 is a cross-sectional view taken through line 9-9 in FIG. 8 of the coolant section cartridge of FIG. 8; and

FIG. 10 is a cross-sectional view taken through line 10-10 in FIG. 7 of one coolant section of the cooling device of FIG. 7.

### DETAILED DESCRIPTION

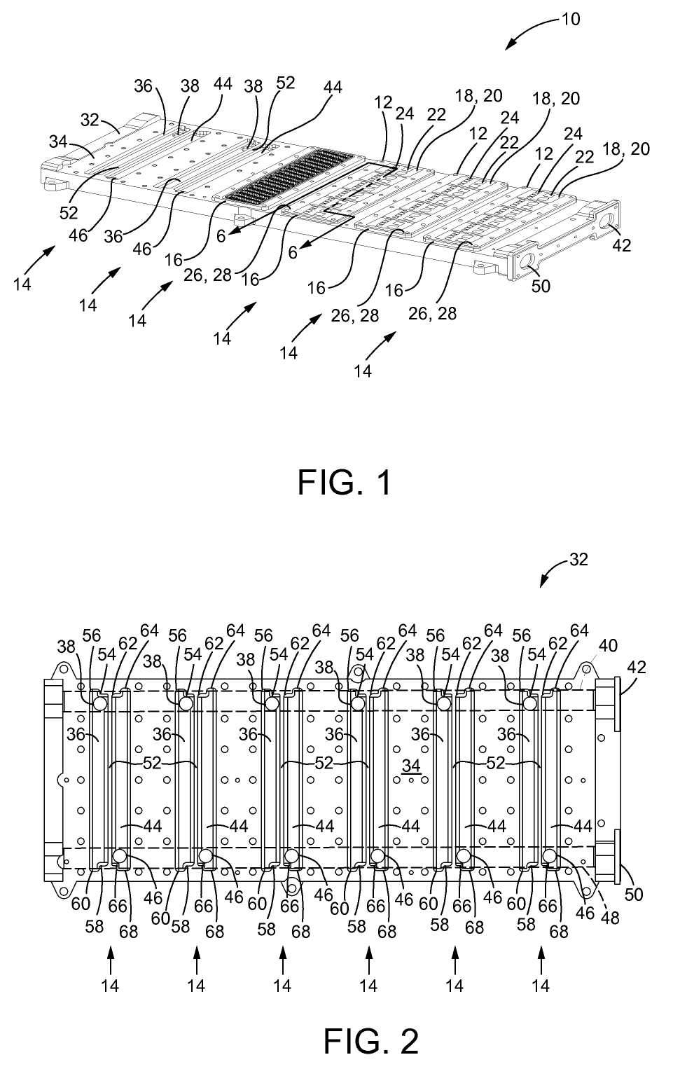

FIG. 1 illustrates an embodiment of a cooling device 10 for IGBT modules 12. The cooling device 10 is designed with a plurality of coolant sections 14 for mounting and cooling corresponding IGBT modules 12. For purposes of illustration, the cooling device 10 is shown with three IGBT modules 12 mounted at corresponding coolant sections 14, one coolant section 14 having a fluid turbulator 16 mounted without an IGBT module 12, and two coolant sections 14 without IGBT modules 12 and fluid turbulators 16. The fluid turbulator 16 is illustrated and described more fully hereinafter. The IGBT modules 12 and corresponding fluid turbulators 16 will be mounted at each coolant section 14 during use. The number of coolant sections 14 may be varied as necessary to accommodate the requirements of a particular implementation of the electric components. IGBT modules are provided as examples of electric components that may be cooled by the cooling device 10. Those skilled in the art will understand that other electric components of a machine, such as electronic control units (ECUs), may be connected to and cooled by cooling devices 10 in accordance with the present disclosure in a similar manner.

Each IGBT module 12 may include one or more IGBTs and/or diodes including a circuit board 18 having a circuit board top surface 20 and a circuit board bottom surface (not shown), and a combination of heat generating components such as transistors 22 and diodes 24 mounted on the circuit board top surface 20 and electrically interconnected as necessary to be able to execute the functions required for the IGBT. The IGBTs may then be mounted on a base plate 26 having a base plate top surface 28 and a base plate bottom surface 30, with the circuit board bottom surface facing and engaging the base plate top surface 28. The cooling device 10 may include a manifold 32 having a manifold top surface 34 defining the coolant sections 14 at which the base plates 26 of the IGBT modules 12 may be mounted on corresponding fluid turbulators 16 to allow coolant to remove heat from the IGBT modules 12 during their operation as will be described more fully below.

The manifold 32 may be shown in greater detail in the top view of FIG. 2 with the IGBT modules 12 and fluid turbulators 16 removed. Each of the coolant sections 14 of the manifold 32 may have a coolant inlet trough 36 defined in the manifold top surface 34. The coolant inlet trough 36 may have a coolant inlet opening 38 placing the coolant inlet trough 36 in fluid communication with a coolant inlet channel 40 extending through one side of the manifold 32 from a manifold coolant inlet 42. The manifold coolant inlet 42 may fluidly connect the manifold 32 with a coolant source (not shown) via an appropriate fluid conduit (not shown) that may provide coolant to the coolant sections 14 via the coolant inlet channel 40 and the coolant inlet openings 38. Each of the coolant sections 14 may also include a coolant outlet trough 44 with a coolant outlet opening 46 placing the coolant outlet trough 44 in fluid communication with a coolant outlet channel 48 extending through an opposite side of the manifold 32 from a manifold coolant outlet 50. The manifold coolant outlet 50 may fluidly connect the manifold 32 with a coolant reservoir (not shown) to which the coolant may be drained from the coolant sections 14 via the coolant outlet openings 46 and the coolant outlet channel 48 after removing heat from the IGBT modules 12. Each coolant section 14 may further include a coolant section divider wall 52 separating the coolant inlet trough 36 from the coolant outlet trough 44.

As will be explained in greater detail below, with the present embodiment of the fluid turbulator 16, a desired mixing of coolant may be created when the coolant flows in a predetermined direction across the fluid turbulator 16. Consequently, it may be desirable to provide a poka-yoke or other mistake-proof alignment feature in the cooling device 10 to ensure that the fluid turbulators 16 can only be installed in the proper orientation. In the present embodiment, the manifold 32 may have structures at the coolant sections 14 that will engage corresponding structures of the fluid turbulators 16 when the fluid turbulators 16 are misoriented. The coolant inlet trough 36 may include a first inlet trough shoulder 54 at a first inlet trough end 56 proximate the coolant inlet opening 38 and a second inlet trough shoulder 58 proximate a second inlet trough end 60. The coolant outlet trough 44 may include a first outlet trough shoulder 62 proximate a first outlet trough end 64 and a second outlet trough shoulder 66 proximate a second outlet trough end 68 that is proximate the coolant outlet opening 46. One of the trough shoulders 54, 58, 62, 66 may have a narrow shoulder width that is less than a wide shoulder width of the other trough shoulders 54, 58, 62, 66. In the illustrated embodiment, the second outlet trough shoulder 66 may have the narrow shoulder width and the other trough shoulders 54, 58, 62 may have the wide shoulder width. As will be discussed further below, a corresponding structure of the fluid turbulator 16 may engage the trough shoulders 54, 58, 62 when the fluid turbulator is misoriented to prevent installation mistakes, while the second outlet trough shoulder 66 will allow insertion of the structure when the fluid turbulator 16 is properly aligned for flow of the coolant and assembly of the cooling device 10.

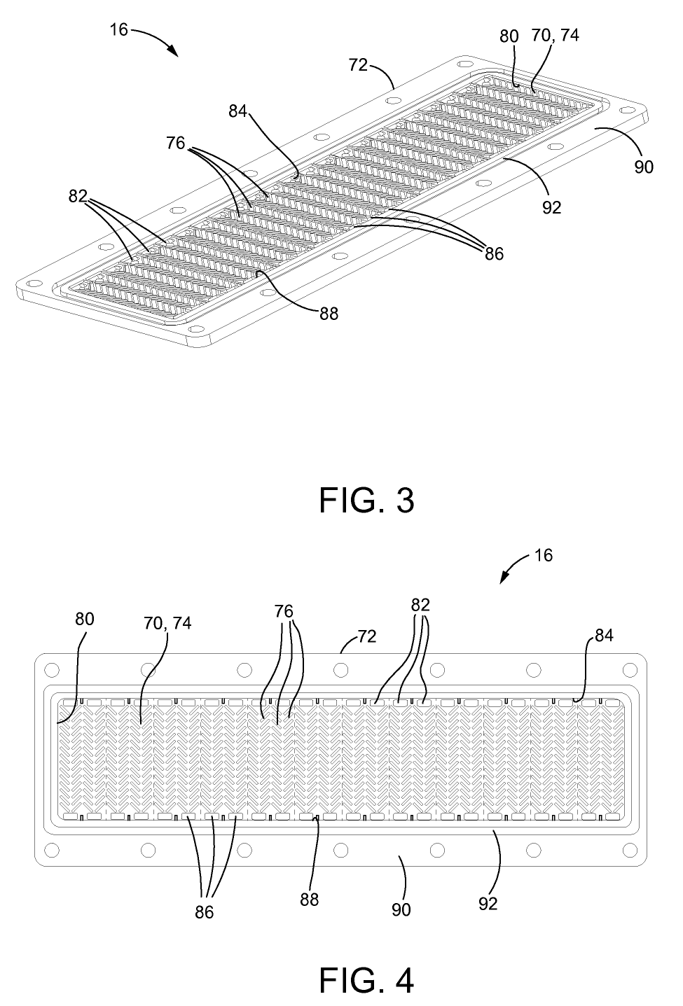

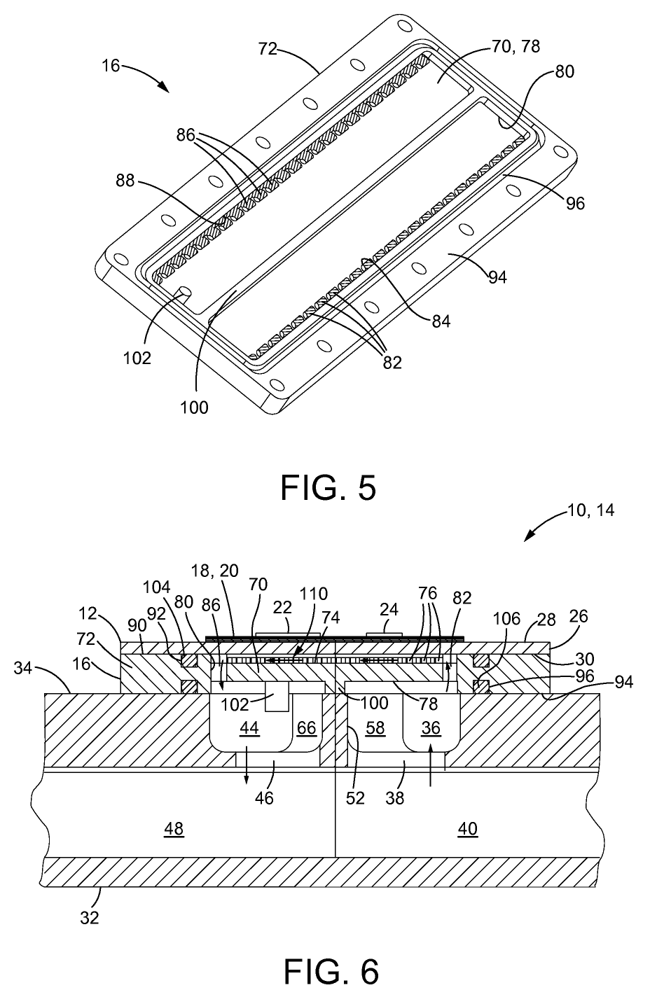

The fluid turbulator 16 is shown in greater detail in FIGS. 3-5. Referring to FIG. 3, the fluid turbulator 16 may include a turbulator plate 70 having a generally rectangular shape that is surrounded and carried by a turbulator carrier 72. The rectangular shape is exemplary, and the turbulator plate 70 may have any appropriate shape to create a desired flow and mixing of coolant. The turbulator plate 70 may include a turbulator plate top surface 74 with a plurality of turbulator fins 76 or other appropriate structures that can enhance mixing extending upwardly therefrom, a turbulator plate bottom surface 78 (FIG. 5), and a turbulator plate outer edge 80 at which the turbulator plate 70 is connected to the turbulator carrier 72. The turbulator plate 70 may have one or more turbulator inlet openings 82 extending through the turbulator plate 70 and aligned above the coolant inlet trough 36 in a first line along an inlet longitudinal edge 84 of the turbulator plate 70. As best seen in FIG. 4, the turbulator plate 70 may also have one or more turbulator outlet openings 86 through the turbulator plate 70 and aligned above the coolant outlet trough 44 in a second line along an outlet longitudinal edge 88 of the turbulator plate 70 opposite the inlet longitudinal edge 84. The turbulator fins 76 may be arranged in rows extending from the line of turbulator inlet openings 82 toward the line of turbulator outlet openings 86 in a manner that will create the desired mixing when coolant flows from the turbulator inlet openings 82 toward the turbulator outlet openings 86. The coolant with desired mixing will contact the base plate bottom surface 30 (see FIG. 6) to transfer heat generated by the transistors 22 and the diodes 24 from the base plate bottom surface 30 to the coolant when the cooling device 10 is assembled as described further below. Of course, the turbulator inlet openings 82 and the turbulator outlet openings 86 may be placed in any appropriate location on the turbulator plate 70 that will facilitate the desired flow and mixing of coolant across the turbulator plate top surface 74.

As seen in FIGS. 3 and 4, the turbulator carrier 72 may have a carrier top surface 90 that may be generally planar and extend outwardly from the turbulator plate outer edge 80. To prevent leakage of coolant after the cooling device 10 is assembled, the carrier top surface 90 may include a turbulator top seal channel 92 defined in the carrier top surface 90 and surrounding the turbulator plate 70. Similarly, the turbulator carrier 72 may have a carrier bottom surface 94 (FIG. 5) that may be generally planer, extend outwardly from the turbulator plate outer edge 80, and have a turbulator bottom seal channel 96 defined therein and surrounding the turbulator plate 70. During assembly, the turbulator top seal channel 92 and the turbulator bottom seal channel 96 may receive flexible seals that will form leak-proof seals as illustrated and described hereinafter.

The bottom isometric view of FIG. 5 more clearly illustrates features of the turbulator plate bottom surface 78. In each coolant section 14, coolant should be prevented from flowing over the coolant section divider wall 52 and between the coolant inlet trough 36 and the coolant outlet trough 44, and thereby bypassing the base plate bottom surface 30 and failing to cause heat removal from the IGBT module 12. Consequently, the turbulator plate bottom surface 78 may engage the coolant section divider wall 52 when the fluid turbulator 16 is installed on the manifold 32 to form a leak-proof seal there between. In one embodiment, a separate wall seal (not shown) may be disposed on the top of the coolant section divider wall 52 and engage the turbulator plate bottom surface 78 when the fluid turbulator 16 is installed to form the leak-proof seal between the coolant inlet trough 36 and the coolant outlet trough 44. In the illustrated embodiment, the turbulator plate bottom surface 78 may include a turbulator plate divider wall 100 extending downwardly from the turbulator plate bottom surface 78 and extending longitudinally parallel to the longitudinal edges 84, 88. The turbulator plate divider wall 100 may align with and engage the coolant section divider wall 52 when the fluid turbulator 16 is aligned and installed on the manifold 32 to form the leak-proof seal as illustrated and discussed below. In a further alternative embodiment, turbulator plate bottom surface 78 may be a planar surface and the coolant section divider wall 52 may extend upwardly above the manifold top surface 34 and engage the turbulator plate bottom surface 78 to form the leak-proof seal when the fluid turbulator 16 is installed. As a still further alternative embodiment, the coolant section divider wall 52 may be omitted and the turbulator plate divider wall 100 may downwardly into the coolant section 14 to replace the coolant section divider wall 52 and separate the coolant section 14 into the coolant inlet trough 36 and the coolant outlet trough 44. Additional combinations of the coolant section divider wall 52, the turbulator plate divider wall 100 and/or the separate wall seal are contemplated.

As discussed above, with the present embodiment of the fluid turbulator 16, the desired mixing of the coolant may be created when the turbulator plate 70 is installed with the turbulator inlet openings 82 disposed above the coolant inlet trough 36 and the turbulator outlet openings 86 disposed above the coolant outlet trough 44. The coolant sections 14 may include trough shoulders 54, 58, 62, 66 as discussed above to function as a first portion of an alignment mechanism for the fluid turbulator 16. As a complimentary feature to the trough shoulders 54, 58, 62, 66, the fluid turbulator 16 may include a turbulator alignment pin 102 extending downwardly from the turbulator plate bottom surface 78 that may be engaged to prevent installation of the fluid turbulator 16 with the wrong orientation.

The turbulator alignment pin 102 and the trough shoulders 54, 58, 62, 66 may be positioned so that the turbulator alignment pin 102 engages the inlet trough shoulders 54, 58 or the first outlet trough shoulder 62 having the wide shoulder width to prevent the fluid turbulator 16 from being installed with the wrong orientation. However, the turbulator alignment pin 102 may not be obstructed by the second outlet trough shoulder 66 due to the narrow shoulder width to allow installation of the fluid turbulator 16 when properly oriented relative to the coolant inlet trough 36 and the coolant outlet trough 44. Of course, the location of the turbulator alignment pin 102 and the trough shoulders 54, 58, 62, 66 or other engagement surfaces may be varied as necessary to achieve the desired design of the cooling device 10 and ensure proper alignment and installation of the fluid turbulator 16. For example, in an embodiment that may reduce the amount of machining required on the manifold 32, a single wide shoulder may be formed in either the coolant inlet trough 36 or the coolant outlet trough 44, and multiple alignment pins may be formed on the turbulator plate bottom surface 78. The multiple alignment pins may be positioned so that one of the alignment pins engage the single wide shoulder when the fluid turbulator 16 is misoriented to prevent improper installation, and none of the alignment pins engage the single wide shoulder when the fluid turbulator 16 is properly oriented to allow proper installation. Moreover, alternative mistake-proof alignment mechanisms may be implemented in cooling devices 10 in accordance with the present disclosure, and such mechanisms are contemplated by the inventors.

Assembly of the IGBT module 12 and the fluid turbulator 16 at one of the coolant sections 14 may be described with reference to FIG. 1 and the cross-sectional view of FIG. 6. The fluid turbulator 16 may be installed at the coolant section 14 with the carrier bottom surface 94 facing and engaging the manifold top surface 34 and surrounding the coolant inlet trough 36 and the coolant outlet trough 44. The base plate 26 of the IGBT module 12 may be installed on the fluid turbulator 16 with the base plate bottom surface 30 facing and engaging the carrier top surface 90 and surrounding the turbulator plate 70. As best seen in FIG. 6, in the illustrated embodiment the turbulator carrier 72 may have a carrier thickness that may be greater than a turbulator plate thickness. The turbulator plate top surface 74 may be disposed below the carrier top surface 90 to provide clearance for the turbulator fins 76 between the turbulator plate top surface 74 and the base plate bottom surface 30. The positioning of the turbulator plate top surface 74 relative to the carrier top surface 90, and correspondingly relative to the base plate bottom surface 30, may also ensure proper placement of the turbulator fins 76 relative to the base plate bottom surface 30 for creation of the desired mixing in the coolant as the coolant flows between the turbulator plate top surface 74 and the base plate bottom surface 30 and through the turbulator fins 76. The turbulator plate bottom surface 78 may be disposed above the carrier bottom surface 94 so that the turbulator plate divider wall 100 may extend downward and engage the coolant section divider wall 52 to form a seal preventing coolant from flowing over the coolant section divider wall 52 between the coolant inlet trough 36 and the coolant outlet trough 44. Of course, other configurations of the fluid turbulator 16 having different relative thicknesses of the turbulator plate 70 and the turbulator carrier 72 are contemplated. For example, turbulator plate 70 and the turbulator carrier 72 may have the same thickness. In such an embodiment, the turbulator plate top surface 74 may be approximately planar with the carrier top surface 90 and the turbulator plate bottom surface 78 may be approximately planar with the carrier bottom surface 94. When installed, the turbulator plate bottom surface 78 may be engaged by the coolant section divider wall 52 to separate the coolant inlet trough 36 and the coolant outlet trough 44. An additional gasket or other spacer structure (not shown) may be installed between the carrier top surface 90 and the base plate bottom surface 30 to prevent the turbulator fins 76 from engaging the base plate bottom surface 30 and to maintain an appropriate spacing there between to achieve the desired coolant mixing and heat removal from the IGBT module 12.

As with other fluid flow devices, it is desirable to prevent leakage of coolant from the coolant sections 14 of the cooling device 10. Consequently, leakage should be prevented at the interfaces between the base plate 26, the turbulator carrier 72 and the manifold 32. A turbulator top seal 104 may be installed within the turbulator top seal channel 92 and configured to engage a surface defining the turbulator top seal channel 92 and the base plate bottom surface 30 to form a top leak-proof seal preventing leakage of coolant between the base plate bottom surface 30 and the carrier top surface 90. Similarly, a turbulator bottom seal 106 may be installed within the turbulator bottom seal channel 96 and configured to engage a surface defining the turbulator bottom seal channel 96 and the manifold top surface 34 to form a bottom leak-proof seal preventing leakage of coolant from the coolant inlet trough 36 and the coolant outlet trough 44 between the carrier bottom surface 94 and the manifold top surface 34. The turbulator top seal 104 and the turbulator bottom seal 106 may be formed separately from the fluid turbulator 16, inserted into the turbulator top seal channel 92 and the turbulator bottom seal channel 96, respectively, and then compressed by the respective base plate bottom surface 30 and the manifold top surface 34 when the cooling device 10 is assembled to form the leak-proof seals. Alternatively, the turbulator top seal 104 and the turbulator bottom seal 106 may be formed by molding an appropriate sealing material into the turbulator top seal channel 92 and the turbulator bottom seal channel 96, respectively, in a manner that allows the molded turbulator top seal 104 and molded turbulator bottom seal 106 to be engaged by the base plate bottom surface 30 and the manifold top surface 34 and form the leak-proof seals.

A heat exchange reservoir 110 may be defined by the base plate bottom surface 30, the turbulator plate top surface 74 and the turbulator carrier 72. The turbulator inlet openings 82 and the turbulator outlet openings 86 may be placed above the coolant inlet trough 36 and the coolant outlet trough 44, respectively, in fluid communication with the heat exchange reservoir 110. Coolant from the coolant source may flow into the manifold 32 through the manifold coolant inlet 42 and fill the coolant inlet channel 40. Coolant may flow through the coolant section 14 as indicated by the arrows in FIG. 6. Coolant from the coolant inlet channel 40 may flow through the coolant inlet opening 38 and into the corresponding the coolant inlet trough 36. The coolant in the coolant inlet trough 36 may then flow through the turbulator inlet openings 82 and into the heat exchange reservoir 110. The turbulator fins 76 on the turbulator plate top surface 74 may cause mixing in the coolant as the coolant flows over the turbulator plate top surface 74 to facilitate heat transfer from the base plate bottom surface 30 to the coolant. The heated coolant may then flow out of the heat exchange reservoir 110 through the turbulator outlet openings 86 and into the coolant outlet trough 44. The coolant may continue flowing out the coolant outlet opening 46 to the coolant outlet channel 48, and out of the manifold 32 through the manifold coolant outlet 50 to the coolant reservoir (not shown) that that may be fluidly connected with the manifold coolant outlet 50 via an appropriate conduit (not shown).

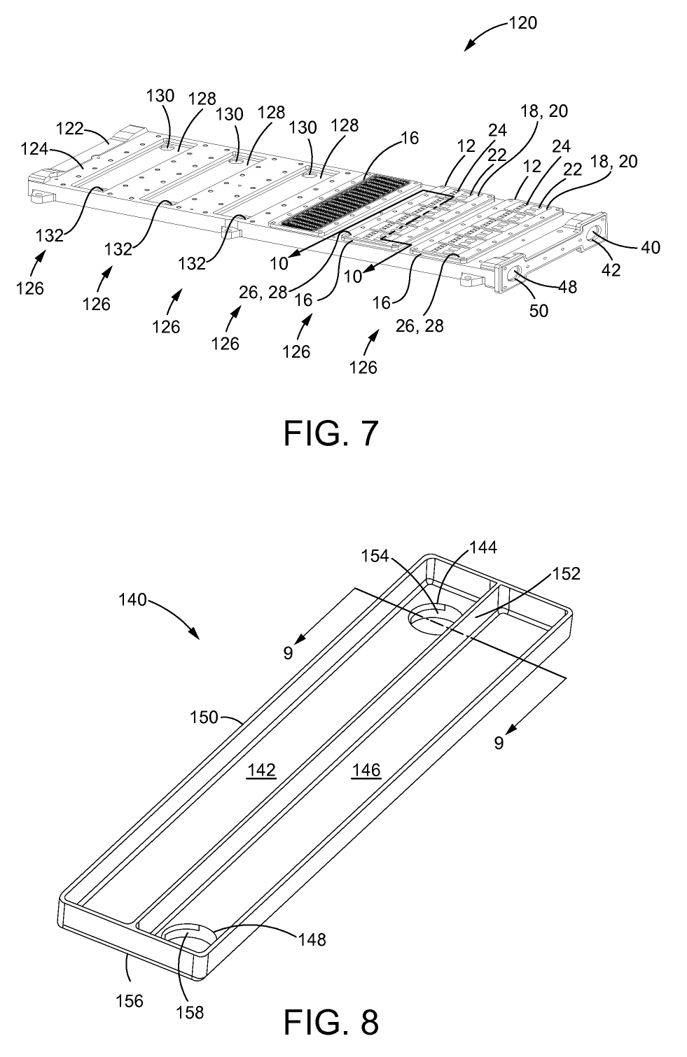

Fabrication of the manifold 32 of the cooling device 10 of FIGS. 1-6 may require machining operations after the manifold 32 is cast, extruded, three dimensionally printed or otherwise formed to form each of the coolant inlet troughs 36 and the coolant outlet troughs 44 in the manifold top surface 34. Each additional machining operation may increase the cost of the cooling device 10. In an alternative embodiment of a cooling device, the operations required to fabricate a manifold may be reduced by using separate cartridges that may provide coolant inlet troughs and the coolant outlet troughs within coolant sections. As shown in FIG. 7, in which similar structures are identified using the same reference numerals as used above, an alternative embodiment of a cooling device 120 may include a manifold 122 having the manifold coolant inlet 42, the coolant inlet channel 40, the coolant outlet channel 48 and the manifold coolant outlet 50 similar to that described above. A manifold top surface 124 may define one or more coolant sections 126 each having a coolant section cartridge recess 128, a coolant section inlet opening 130 fluidly connecting the coolant section cartridge recess 128 with the coolant inlet channel 40, and a coolant section outlet opening 132 fluidly connecting the coolant section cartridge recess 128 with the coolant outlet channel 48.

Referring to FIG. 8, a coolant section cartridge 140 may be provided that may be installed within the coolant section cartridge recess 128 to subdivide the coolant section cartridge recess 128 into coolant inlet and outlet sections. The coolant section cartridge 140 may include a coolant inlet trough 142 with a cartridge coolant inlet opening 144, a coolant outlet trough 146 with a cartridge coolant outlet opening 148, and a cartridge top surface 150. The cartridge coolant inlet opening 144 and the cartridge coolant outlet opening 148 may be positioned to align with the coolant section inlet opening 130 and the coolant section outlet opening 132, respectively, when the coolant section cartridge 140 is installed within the coolant section cartridge recess 128.

The carrier bottom surface 94 (FIG. 10) of the fluid turbulator 16 may face and engage the cartridge top surface 150 and surround the coolant inlet trough 142 and the coolant outlet trough 146 when the coolant section cartridge 140 is attached to the fluid turbulator 16. The coolant section cartridge 140 in the illustrated embodiment may further include a cartridge divider wall 152 separating the coolant inlet trough 142 from the coolant outlet trough 146. When assembled, the turbulator plate divider wall 100 may align with and engage the cartridge divider wall 152 to separate the coolant inlet trough 142 and the coolant outlet trough 146 and prevent coolant flow between the coolant inlet trough 142 and the coolant outlet trough 146. Alternatively, other configurations and combinations of the turbulator plate divider wall 100, the cartridge divider wall 152 and/or a separate wall seal such as those describe for the embodiment of FIGS. 1-6 may be utilized in a particular implementation. The turbulator inlet openings 82 may fluidly connect the coolant inlet trough 142 and the cartridge coolant inlet opening 144 with the turbulator plate top surface 74, and the turbulator outlet openings 86 may fluidly connect the coolant outlet trough 146 and the cartridge coolant outlet opening 148 with the turbulator plate top surface 74 so that coolant can flow from the coolant inlet trough 142 over the turbulator plate top surface 74 and through the turbulator fins 76, and out to the coolant outlet trough 146.

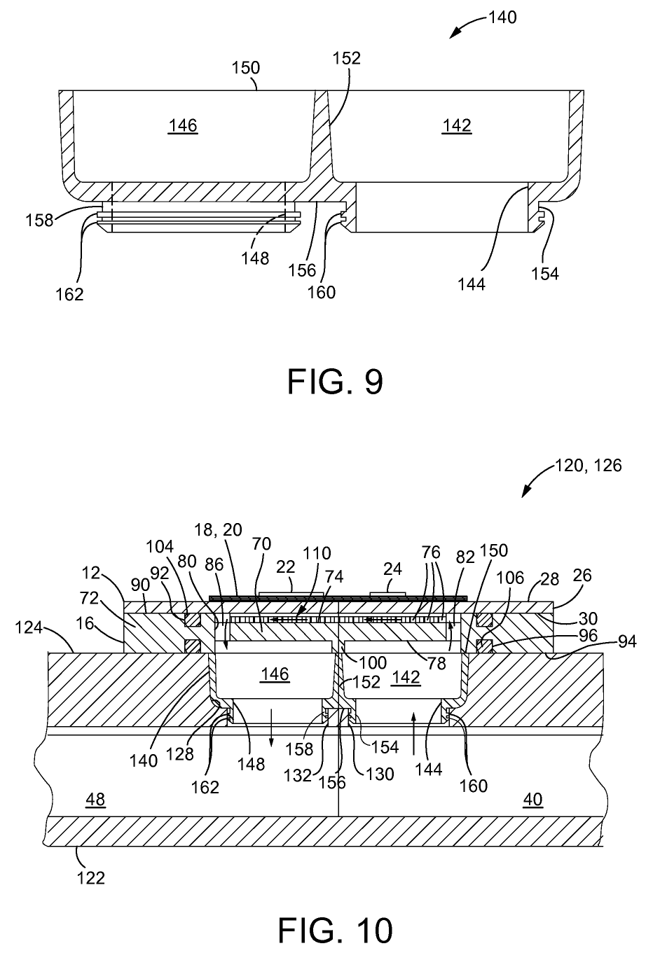

To provide a sufficient seal between the coolant section cartridge 140 and the coolant section cartridge recess 128, the coolant section cartridge 140 may include a coolant inlet opening cylinder 154 (FIGS. 8 and 9) extending downwardly from a cartridge bottom wall 156 at the cartridge coolant inlet opening 144, and a coolant outlet opening cylinder 158 extending downwardly from the cartridge bottom wall 156 at the cartridge coolant outlet opening 148. The coolant inlet opening cylinder 154 and the coolant outlet opening cylinder 158 may be received by the coolant section inlet opening 130 and the coolant section outlet opening 132, respectively, when the coolant section cartridge 140 is installed in the coolant section cartridge recess 128. The coolant inlet opening cylinder 154 may include one or more coolant inlet opening annular ribs 160 that may engage the coolant section inlet opening 130 to form an inlet opening leak-proof seal, and the coolant outlet opening cylinder 158 may include one or more coolant outlet opening annular ribs 162 that may engage the coolant section outlet opening 132 to form an outlet opening leak-proof seal. In the illustrated embodiment, the annular ribs 160, 162 are integral components of the coolant section cartridge 140 formed on the respective opening cylinders 154, 158. The coolant section cartridge 140 may be molded or otherwise formed from a deformable or crushable material such that the annular ribs 160, 162 may be compressed or crushed between the opening cylinders 154, 158 and the walls of the openings 130, 132 when the coolant section cartridge 140 is installed. Alternatively, the annular ribs 160, 162 may be separate components formed from a resilient sealing material that is over-molded or otherwise installed on the opening cylinders 154, 158 after the coolant section cartridge 140 is formed.

Referring to the cross-sectional view of one of the coolant sections 126 shown in FIG. 10, the coolant section cartridge 140 may be installed at the coolant section 126 with the coolant section cartridge 140 disposed within the coolant section cartridge recess 128 with the cartridge coolant inlet opening 144 and the cartridge coolant outlet opening 148 aligned with the coolant section inlet opening 130 and the coolant section outlet opening 132, respectively. The fluid turbulator 16 may be installed at the coolant section 126 with the carrier bottom surface 94 facing and engaging the manifold top surface 34 and the cartridge top surface 150, and surrounding the coolant section cartridge recess 128 and the coolant section cartridge 140. In some implementations, the fluid turbulator 16 and the coolant section cartridge 140 may be combined as a turbulator cartridge assembly that may be preassembled before installation in the coolant section 126. Though not shown in the illustrated embodiment, the fluid turbulator 16 and the coolant section cartridge 140 may include appropriate poka-yoke or mistake-proof alignment features such as those described above to ensure that the fluid turbulator 16 and the coolant section cartridge 140 can only be assembled in the proper orientation relative to each other. Once the coolant section cartridge 140 is aligned with the coolant section cartridge recess 128, the opening cylinders 154, 158 may be pressed into the openings 130, 132, respectively, with the annular ribs 160, 162 being compressed or crushed to form the opening leak-proof seals. The coolant section cartridge 140 may be pressed into the coolant section cartridge recess 128 until the cartridge bottom wall 156 is engaged by the coolant section cartridge recess 128.

The base plate bottom surface 30 may face and engage the carrier top surface 90 and surround the turbulator plate 70 so that a heat exchange reservoir 110 is defined by the base plate bottom surface 30, the turbulator plate top surface 74 and the turbulator carrier 72 as described above. The turbulator inlet openings 82 and the turbulator outlet openings 86 may fluidly connect the coolant inlet trough 142 and the coolant outlet trough 146, respectively, with the heat exchange reservoir 110. As configured, coolant from the coolant inlet channel 40 may flow into the coolant inlet trough 142, through the turbulator inlet openings 82 into the heat exchange reservoir 110, and out of the heat exchange reservoir 110 through the turbulator outlet openings 86 into the coolant outlet trough 146 and to the coolant outlet channel 48 in a similar manner as described for the coolant sections 14 in the cooling device 10.

As discussed above, the fluid turbulator 16 and the coolant section cartridge 140 may be pre-assembled prior to installation in the coolant section cartridge recess 128. Alternatively, the fluid turbulator 16 and the coolant section cartridge 140 may be formed together as a single unitary component in a signal casting, molding or extruding process or three-dimensional printing operation. In still further alternative embodiments, the turbulator plate 70 and the coolant section cartridge 140 may be fabricated as a single unitary component, and with the turbulator carrier 72 being formed as a separated component that may be installed around the turbulator plate 70 and between the manifold top surface 124 and the base plate bottom surface 30 after the turbulator plate 70 and coolant section cartridge 140 is installed in the coolant section cartridge recess 128. Other alternative configurations for manufacturing and assembling the cooling device 120 shown in FIG. 10 will be apparent to those skilled in the art and are contemplated by the inventors as having use in cooling devices 120 in accordance with the present disclosure.

### INDUSTRIAL APPLICABILITY

The designs of the cooling devices 10, 120 in accordance with the present disclosure may be more efficient and cost effective positioning the elements so that the desired mixing is created in the coolant flowing through the heat exchange reservoir 110 and heat may be transferred from the IGBT module 12 to the coolant in an efficient manner. In previous cooling device designs, a turbulator plate may be dropped into a recess of a manifold, and then a base plate of an IGBT module may be attached above the turbulator plate via an intervening sealing system. The tolerance stack up between the IGBT module, the turbulator plate, the sealing system and the manifold can lead to performance issues when the turbulator fins on the turbulator plate are disposed too close to or too far from the bottom surface of the base plate and the desired mixing in the coolant is not achieved. Reliably ensuring proper spacing between the turbulator fins and the base plate requires precise control of the tolerances of the assembled components, which increases the overall cost of the cooling device.

In the present design, the manufacturing process is simplified by the integration of the fluid turbulator support and sealing systems into the fluid turbulator 16. The turbulator plate 70 and the turbulator carrier 72 may be fabricated as a single unitary component. The fluid turbulator 16 may be formed from an appropriate non-ferrous material that will not interfere with the operation of the IGBT modules 12 from an appropriate fabrication process such as three dimensional printing, injection molding, machining and the like. Of course, any appropriate ferrous or non-ferrous materials may be used to fabricate the fluid turbulator as the electric components can function as designed. Because the turbulator plate 70 is carried by the turbulator carrier 72, tolerance control over the length of the turbulator fins 76 above the turbulator plate top surface 74, and over the offset of the turbulator plate top surface 74 below the carrier top surface 90 or over the thickness of a gasket or other structure as discussed above, may be sufficient to ensure that the turbulator fins 76 are positioned properly relative to the base plate bottom surface 30.

While the preceding text sets forth a detailed description of numerous different embodiments, it should be understood that the legal scope of protection is defined by the words of the claims set forth at the end of this patent. The detailed description is to be construed as exemplary only and does not describe every possible embodiment since describing every possible embodiment would be impractical, if not impossible. Numerous alternative embodiments could be implemented, using either current technology or technology developed after the filing date of this patent, which would still fall within the scope of the claims defining the scope of protection.

It should also be understood that, unless a term was expressly defined herein, there is no intent to limit the meaning of that term, either expressly or by implication, beyond its plain or ordinary meaning, and such term should not be interpreted to be limited in scope based on any statement made in any section of this patent (other than the language of the claims). To the extent that any term recited in the claims at the end of this patent is referred to herein in a manner consistent with a single meaning, that is done for sake of clarity only so as to not confuse the reader, and it is not intended that such claim term be limited, by implication or otherwise, to that single meaning.

What is claimed is:

1. A cooling device for an electric component having a base plate with a base plate top surface and a base plate bottom surface, the electric component further having a heat generating component disposed on the base plate top surface, the cooling device comprising:
a manifold having a manifold top surface defining a coolant section having a coolant inlet trough with a coolant inlet opening fluidly connecting the coolant inlet trough with a coolant source, and a coolant outlet trough with a coolant outlet opening fluidly connecting the coolant outlet trough with a coolant reservoir; and
a fluid turbulator comprising:
a turbulator plate having a turbulator plate top surface with at least one turbulator fin extending upwardly therefrom, a turbulator plate bottom surface, and a turbulator inlet opening and a turbulator outlet opening through the turbulator plate, and
a turbulator carrier surrounding the turbulator plate and having a carrier top surface and a carrier bottom surface,
wherein the fluid turbulator is installed at the coolant section with the carrier bottom surface facing and engaging the manifold top surface and surrounding the coolant inlet trough and the coolant outlet trough, and the base plate bottom surface facing and engaging the carrier top surface and surrounding the turbulator plate so that a heat exchange reservoir is defined by the base plate bottom surface, the turbulator plate top surface and the turbulator carrier with the turbulator inlet opening and the turbulator outlet opening fluidly connecting the coolant inlet trough and the coolant outlet trough, respectively, with the heat exchange reservoir so that coolant from the coolant source flows into the coolant inlet trough, through the turbulator inlet opening into the heat exchange reservoir, and out of the heat exchange reservoir through the turbulator outlet opening into the coolant outlet trough and to the coolant reservoir.

2. The cooling device of claim 1, wherein the turbulator carrier includes a turbulator top seal channel defined in the carrier top surface and surrounding the turbulator plate, and a turbulator bottom seal channel defined in the carrier bottom surface and surrounding the turbulator plate, and wherein the cooling device comprises:
a turbulator top seal installed within the turbulator top seal channel and engaging the turbulator top seal channel and the base plate bottom surface to form a top leak-proof seal preventing leakage of coolant from the heat exchange reservoir between the base plate bottom surface and the carrier top surface; and
a turbulator bottom seal installed within the turbulator bottom seal channel and engaging the turbulator bottom seal channel and the manifold top surface to form a bottom leak-proof seal preventing leakage of coolant from the coolant inlet trough and the coolant outlet trough between the carrier bottom surface and the manifold top surface.

3. The cooling device of claim 1, wherein the turbulator inlet opening comprises a plurality of turbulator inlet openings through the turbulator plate and aligned in a first line along an inlet longitudinal edge of the turbulator plate, and wherein the turbulator outlet opening comprises a plurality of turbulator outlet openings through the turbulator plate and aligned in a second line along an outlet longitudinal edge of the turbulator plate opposite the inlet longitudinal edge.

4. The cooling device of claim 1, wherein the manifold comprises a coolant section divider wall separating the coolant inlet trough from the coolant outlet trough, and wherein the turbulator plate bottom surface engages the coolant section divider wall when the fluid turbulator is installed on the manifold.

5. The cooling device of claim 4, wherein the turbulator plate bottom surface comprises turbulator plate divider wall extending downwardly therefrom, wherein the turbulator plate divider wall aligns with and engages the coolant section divider wall when the fluid turbulator is installed on the manifold.

6. The cooling device of claim 1, wherein the fluid turbulator comprises a turbulator alignment pin extending downwardly from the turbulator plate bottom surface, wherein the coolant inlet trough comprises a first inlet trough shoulder proximate a first inlet trough end and a second inlet trough shoulder proximate a second inlet trough end, and the coolant outlet trough comprises a first outlet trough shoulder proximate a first outlet trough end and a second outlet trough shoulder proximate a second outlet trough end, wherein one of the trough shoulders has a narrow shoulder width that is less than a wide shoulder width of the other of the trough shoulders, and wherein the turbulator alignment pin and the trough shoulders are positioned so that the turbulator alignment pin engages the other of the trough shoulders having the wide shoulder width to prevent the fluid turbulator from being installed when the fluid turbulator is not properly oriented relative to the coolant inlet trough and the coolant outlet trough, and the turbulator alignment pin is proximate to and does not engage the one of the trough shoulders having the narrow shoulder width to allow installation of the fluid turbulator when the fluid turbulator is properly oriented relative to the coolant inlet trough and the coolant outlet trough.

7. A fluid turbulator for a cooling device for an electric component, the fluid turbulator comprising:
a turbulator plate having a turbulator plate top surface, a turbulator plate bottom surface, a turbulator plate outer edge, a plurality of turbulator fins extending upwardly from the turbulator plate top surface, a turbulator inlet opening through the turbulator plate and a turbulator outlet opening through the turbulator plate, the turbulator plate having a turbulator plate thickness; and
a turbulator carrier having a carrier top surface, a carrier bottom surface and a carrier thickness, the turbulator carrier surrounding the turbulator plate at the turbulator plate outer edge, wherein the carrier thickness is greater than the turbulator plate thickness, with the turbulator plate top surface being below the carrier top surface and the turbulator plate bottom surface being above the carrier bottom surface.

8. The fluid turbulator of claim 7, wherein the turbulator carrier includes a turbulator top seal channel defined in the carrier top surface and surrounding the turbulator plate, and a turbulator bottom seal channel defined in the carrier bottom surface and surrounding the turbulator plate.

9. The fluid turbulator of claim 7, wherein the turbulator inlet opening comprises a plurality of turbulator inlet openings through the turbulator plate and aligned in a first line along an inlet longitudinal edge of the turbulator plate, and wherein the turbulator outlet opening comprises a plurality of turbulator outlet openings through the turbulator plate and aligned in a second line along an outlet longitudinal edge of the turbulator plate opposite the inlet longitudinal edge.

10. The fluid turbulator of claim 7, wherein the turbulator plate is rectangular and has a turbulator plate length and a turbulator plate width, and wherein the turbulator plate bottom surface comprises turbulator plate divider wall extending downwardly therefrom and extending longitudinally along the turbulator plate length to separate the turbulator plate into a turbulator plate inlet section including the turbulator inlet opening and a turbulator plate outlet section including the turbulator outlet opening.

11. A turbulator cartridge assembly, comprising:
the fluid turbulator of claim 7; and
a coolant section cartridge having a coolant inlet trough with a cartridge coolant inlet opening, a coolant outlet trough with a cartridge coolant outlet opening, and a cartridge top surface, wherein the carrier bottom surface faces and engages the cartridge top surface and surrounds the coolant inlet trough and the coolant outlet trough, and wherein the turbulator inlet opening fluidly connects the coolant inlet trough and the cartridge coolant inlet opening with the turbulator plate top surface, and the turbulator outlet opening fluidly connects the coolant outlet trough and the cartridge coolant outlet opening with the turbulator plate top surface.

12. The turbulator cartridge assembly of claim 11, wherein the coolant section cartridge comprises a cartridge divider wall separating the coolant inlet trough from the coolant outlet trough, and wherein the turbulator plate bottom surface engages the cartridge divider wall.

13. The turbulator cartridge assembly of claim 12, wherein the turbulator plate bottom surface comprises turbulator plate divider wall extending downwardly therefrom, and the turbulator plate divider wall aligns with and engages the cartridge divider wall.

14. The turbulator cartridge assembly of claim 11, wherein the fluid turbulator and the coolant section cartridge are formed together as a single unitary component.

15. A cooling device for an electric component having a base plate with a base plate top surface having a heat generating component disposed thereon and a base plate bottom surface, the cooling device comprising:
a manifold having a manifold top surface defining a coolant section having coolant section cartridge recess, and a coolant section inlet opening for placing the coolant section cartridge recess in fluid communication with a coolant source, and a coolant section outlet opening for placing the coolant section cartridge recess in fluid communication with a coolant reservoir;
a coolant section cartridge having a coolant inlet trough with a cartridge coolant inlet opening, a coolant outlet trough with a cartridge coolant outlet opening, and a cartridge top surface, wherein the cartridge coolant inlet opening and the cartridge coolant outlet opening are positioned to align with the coolant section inlet opening and the coolant section outlet opening, respectively, when the coolant section cartridge is disposed within the coolant section cartridge recess; and
a fluid turbulator comprising:
a turbulator plate having a turbulator plate top surface with at least one turbulator fin extending upwardly therefrom, a turbulator plate bottom surface, and a turbulator inlet opening and a turbulator outlet opening through the turbulator plate, and
a turbulator carrier surrounding the turbulator plate and having a carrier top surface and a carrier bottom surface,
wherein the coolant section cartridge is installed at the coolant section with the coolant section cartridge disposed within the coolant section cartridge recess with the cartridge coolant inlet opening and the cartridge coolant outlet opening aligned with the coolant section inlet opening and the coolant section outlet opening, respectively, and
wherein the fluid turbulator is installed at the coolant section with the carrier bottom surface facing and engaging the manifold top surface and the cartridge top surface, and the base plate bottom surface facing and engaging the carrier top surface and surrounding the turbulator plate so that a heat exchange reservoir is defined by the base plate bottom surface, the turbulator plate top surface and the turbulator carrier, with the turbulator inlet opening and the turbulator outlet opening fluidly connecting the coolant inlet trough and the coolant outlet trough, respectively, with the heat exchange reservoir so that coolant from the coolant source flows into the coolant inlet trough, through the turbulator inlet opening into the heat exchange reservoir, and out of the heat exchange reservoir through the turbulator outlet opening into the coolant outlet trough and to the coolant reservoir.

16. The cooling device of claim 15, wherein the turbulator carrier includes a turbulator top seal channel defined in the carrier top surface and surrounding the turbulator plate, and a turbulator bottom seal channel defined in the carrier bottom surface and surrounding the turbulator plate, and wherein the cooling device comprises:
a turbulator top seal installed within the turbulator top seal channel and engaging the turbulator top seal channel and the base plate bottom surface to form a top leak-proof seal preventing leakage of coolant from the heat exchange reservoir between the base plate bottom surface and the carrier top surface; and
a turbulator bottom seal installed within the turbulator bottom seal channel and engaging the turbulator bottom seal channel and the manifold top surface to form a bottom leak-proof seal preventing leakage of coolant from the coolant inlet trough and the coolant outlet trough between the carrier bottom surface and the manifold top surface.

17. The cooling device of claim 15, wherein the coolant section cartridge comprises a cartridge divider wall separating the coolant inlet trough from the coolant outlet trough, and wherein the turbulator plate bottom surface engages the cartridge divider wall when the fluid turbulator is installed on the manifold.

18. The cooling device of claim 17, wherein the turbulator plate bottom surface comprises turbulator plate divider wall extending downwardly therefrom, wherein the turbulator plate divider wall aligns with and engages the cartridge divider wall when the fluid turbulator is installed on the manifold.

19. The cooling device of claim 15, wherein the coolant section cartridge comprises:
a coolant inlet opening cylinder extending downwardly from a cartridge bottom wall at the cartridge coolant inlet opening of the coolant section cartridge; and
a coolant outlet opening cylinder extending downwardly from the cartridge bottom wall at the cartridge coolant outlet opening of the coolant section cartridge, wherein the coolant inlet opening cylinder is received by the coolant section inlet opening and the coolant outlet opening cylinder is received by the coolant section outlet opening when the coolant section cartridge is installed in the coolant section cartridge recess.

20. The cooling device of claim 19, wherein the coolant inlet opening cylinder comprises a coolant inlet opening annular rib that engages the coolant section inlet opening to form an inlet opening leak-proof seal when the coolant section cartridge is installed in the coolant section cartridge recess, and the coolant outlet opening cylinder comprises a coolant outlet opening annular rib that engages the coolant section outlet opening to form an outlet opening leak-proof seal when the coolant section cartridge is installed in the coolant section cartridge recess.
